(19) United States
(12) Patent Application Publication
(10) Pub. No.: US 2008/0053687 A1
(43) Pub. Date: Mar. 6, 2008

(54) PRINTED CIRCUIT BOARD ABLE TO SUPPRESS SIMULTANEOUS SWITCHING NOISE

(75) Inventors: LIANG-YAO CHANG, Tu-Cheng (TW); SHOU-KUO HSU, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/760,800

(22) Filed: Jun. 11, 2007

(30) Foreign Application Priority Data
Sep. 1, 2006 (CN) 200610062434.X

(51) Int. Cl. H05K 1/00

(52) U.S. Cl. 174/258

(57) ABSTRACT

A printed circuit board includes a power plane, a ground plane insulated from the power plane, and at least one via. The power plane includes two power modules, an insulating medium for insulating the two power modules, and a signal transmission line positioned between the two power modules and insulated from the two power modules by the insulating medium. The at least one via connects the signal transmission line with the ground plane for conducting simultaneous switching noise (SSN) transmitted to the power modules to the ground plane.

### BACKGROUND OF THE INVENTION

1. Field of the Invention

The present invention relates to printed circuit boards, and particularly to suppression of simultaneous switching noise (SSN) in a printed circuit board (PCB).

2. Description of Related Art

As the density of integrated circuits on PCBs increases, the problems associated with signal switching noise become greater. Many integrated circuits have a large number of input/output (I/O) drivers. Several hundred drivers may be present in integrated circuits, and this number will undoubtedly become greater as packaging density increases in the future. Noise that occurs in the PCB when a large number of drivers simultaneously switch from one state to another is known as SSN. The problem may be even more acute when the drivers all switch in the same direction (e.g. high to low). When a large number of drivers switch simultaneously, various signal integrity problems may occur. For example, a conventional PCB as shown in FIG. 3 includes a ground plane 100, a power plane 200 insulated from the ground plane 100 by a fiberglass material, and two integrated circuits A, B positioned on a surface plane (not shown) of the PCB. The power plane 200 includes two power modules 210, 220 insulated from each other by an insulating medium 230 made up of fiberglass material to respectively provide power supply for the integrated circuits A, B. When drivers in the integrated circuit A simultaneously switch from one state to another, SSN from the integrated circuit A can be transmitted to the power module 220 via the power module 210 and an equivalent coupling capacitance formed by the power modules 210, 220 and the insulating medium 230. Then the integrated circuit B may receive the SSN and cause incorrect actions.

What is needed, therefore, is a PCB with suppressed SSN therein.

### SUMMARY OF THE INVENTION

A printed circuit board for suppression of simultaneous switching noise therein is provided. In a preferred embodiment, the printed circuit board includes a power plane, a ground plane insulated from the power plane, and at least one via. The power plane includes two power modules, an insulating medium for insulating the two power modules from each other, and a signal transmission line positioned between the two power modules and insulated from the two power modules by the insulating medium. The at least one via connects the signal transmission line with the ground plane.

Other advantages and novel features will become more apparent from the following detailed description when taken in conjunction with the accompanying drawings, in which:

### BRIEF DESCRIPTION OF THE DRAWINGS

FIG. 1 is an isometric, schematic diagram of a printed circuit board in accordance with a preferred embodiment of the present invention;

FIG. 2 is an isometric, schematic diagram of a printed circuit board in accordance with another preferred embodiment of the present invention;

FIG. 3 is a schematic diagram of a conventional printed circuit board; and

FIG. 4 is a graph of insertion loss versus frequency in the PCBs of FIGS. 1, 2, and 3.

### DETAILED DESCRIPTION OF THE INVENTION

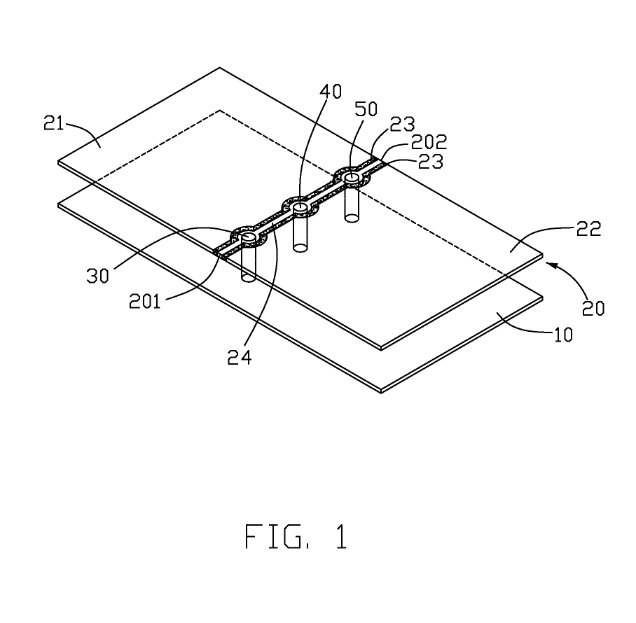

Referring to FIG. 1, a printed circuit board (PCB) in accordance with an embodiment of the present invention includes a ground plane 10, a power plane 20, and vias 30, 40, 50. The power plane 20 includes two power modules 21, 22 for respectively providing power supply for two electronic components (not shown), two insulating mediums 23 for insulating the power module 21 from the power module 22, and a signal transmission line 24 positioned between the power modules 21, 22 and insulated from the power modules 21, 22 by the insulating mediums 23. The ground plane 10 is insulated from the power plane 20 by fiberglass material (not shown). The insulating mediums 23 are made up of fiberglass. The power plane 20 includes a front side 201 and a rear side 202. The insulating mediums 23 and the signal transmission line 24 are traced from the front side 201 to the rear side 202. The vias 30, 40, 50 electrically connect the signal transmission line 24 with the ground plane 10.

The power module 21 and the signal transmission line 24 forms an equivalent coupling capacitance. The power module 22 and the signal transmission line 24 forms an equivalent coupling capacitance. The equivalent coupling capacitances are connected to the ground plane 10 by the vias 30, 40, 50. When drivers in one of the electronic components above the power modules 21 or 22 of the power plane 20 simultaneously switch from one state to another, simultaneous switching noise (SSN) transmitted from the electronic components to the power module 21 or the power module 22 can be conducted to the ground plane 10 via the equivalent coupling capacitances before be transmitted to the power module 22 or the power module 21. Therefore, the SSN in the PCB is suppressed.

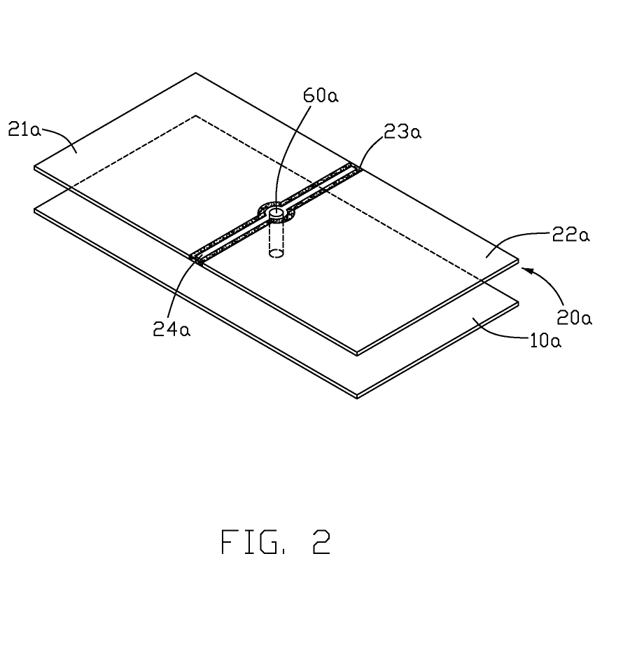

Referring to FIG. 2, a PCB in accordance with another embodiment of the present invention includes a ground plane 10a, a power plane 20a, and a via 60a. The power plane 20a includes two power modules 21a, 22a, an insulating medium 23a for insulating the power module 21a from the power module 22a, and a signal transmission line 24a insulated from the power modules 21a, 22a by the insulating medium 23a. The via 60a connects the signal transmission line 24a and the ground plane 10a.

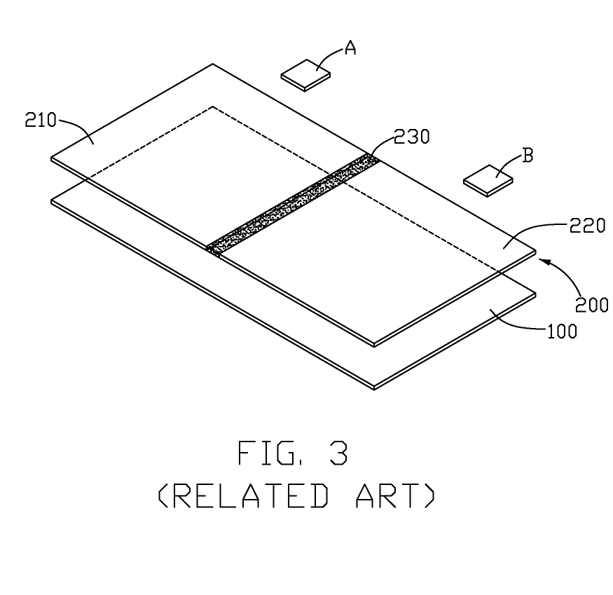

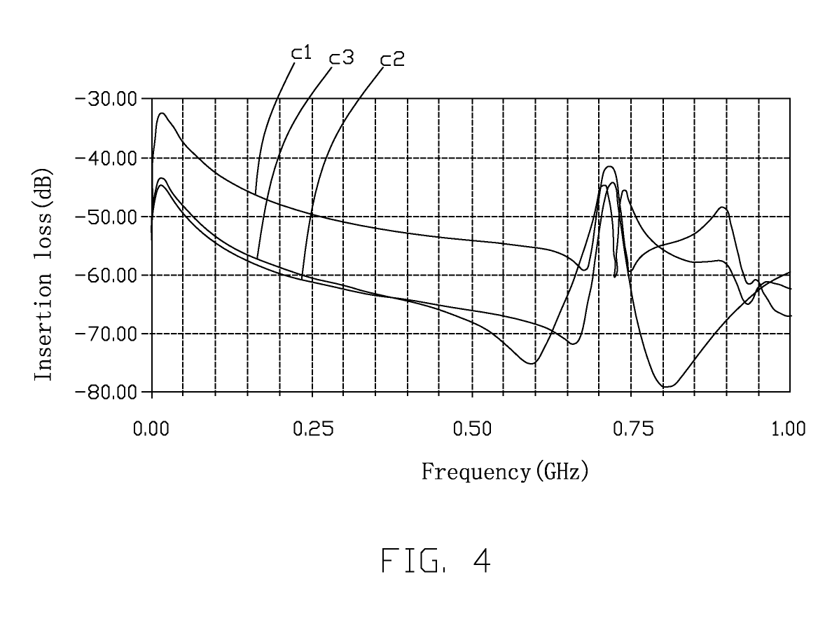

FIG. 4 shows a graph comparing insertion loss versus frequency in the PCBs of FIGS. 1, 2, and 3. Curves c2, c3, c1 are respective insertion loss versus frequency curves of the PCBs of FIGS. 1, 2, and 3. The curves c2, c3 show the insertion loss of the PCBs of FIG. 1, 2 are less than the insertion loss of the PCB of FIG. 3 when the frequency is less than 0.7 GHz. Less insertion loss indicates a better effect of blocking the SSN.

The embodiments were chosen and described in order to explain the principles of the invention and their practical application so as to enable others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A printed circuit board comprising:
a power plane comprising two power modules, an insulating medium for insulating the two power modules from each other, and a signal transmission line positioned between the two power modules and insulated from the two power modules by the insulating medium;
a ground plane insulated from the power plane; and
at least one via connecting the signal transmission line with the ground plane.

2. The printed circuit board as claimed in claim 1, wherein the power plane comprises a front side and a rear side, the insulating medium is traced from the front side to the rear side.

3. The printed circuit board as claimed in claim 2, wherein the signal transmission line is traced from the front side to the rear side.

4. The printed circuit board as claimed in claim 1, wherein the insulating medium is made up of fiberglass material.

5. The printed circuit board as claimed in claim 1, wherein each power module and the signal transmission line form an equivalent coupling capacitance.

6. The printed circuit board as claimed in claim 5, wherein the equivalent coupling capacitance is connected to the ground plane by the at least one via.

7. A printed circuit board comprising:
a plane comprising two power modules, an insulating medium configured for insulating the two power modules from each other, a signal transmission line positioned between the two power modules and insulated from the two power modules by the insulating medium;
a ground portion spaced and insulated from the power modules; and
at least one via connecting the signal transmission line with the ground portion.

8. The printed circuit board as claimed in claim 7, wherein the plane comprises a front side and a rear side, the insulating medium is traced from the front side to the rear side.

9. The printed circuit board as claimed in claim 8, wherein the signal transmission line is traced from the front side to the rear side.

10. The printed circuit board as claimed in claim 7, wherein the insulating medium is made up of fiberglass.

11. A printed circuit board comprising:
a power plane defining a longitudinal direction and a lateral direction traverse to the longitudinal direction, the power plane comprising two power modules arranged in the longitudinal direction with a space extending in the lateral direction formed therebetween, and a signal transmission line positioned in the space with an insulating medium positioned at opposite sides thereof for insulating the signal transmission line from the two power modules;
a ground plane parallel to and insulated from the power plane; and
at least one via electrically connecting the signal transmission line with the ground plane.

12. The printed circuit board as claimed in claim 11, wherein the power plane comprises a side and an opposite side in the longitudinal direction, and the insulating medium is traced from the side edge to the opposite side edge.

13. The printed circuit board as claimed in claim 12, wherein the side and the opposite sides are perpendicular to the power plane.

14. The printed circuit board as claimed in claim 11, wherein the insulating medium is made up of fiberglass material.

15. The printed circuit board as claimed in claim 11, wherein each of the power modules and the signal transmission line form an equivalent coupling capacitance.
